(19) United States
(12) Patent Application Publication
(10) Pub. No.: US 2026/0013242 A1
(43) Pub. Date: Jan. 8, 2026

(54) IMAGE SENSING DEVICE AND METHOD FOR MANUFACTURING THE SAME

(71) Applicant: SK hynix Inc., Icheon-si (KR)

(72) Inventor: Young Woong DO, Icheon-si (KR)

(21) Appl. No.: 18/948,284

(22) Filed: Nov. 14, 2024

(30) Foreign Application Priority Data
Jul. 8, 2024 (KR) 10-2024-0089431

(51) Int. Cl. H01L 27/146

(52) U.S. Cl. CPC H10F 39/8023; H10F 39/024; H10F 39/8053

(57) ABSTRACT

Image sensing devices and methods of manufacturing image sensing devices are disclosed. In an embodiment, an image sensing device includes a circuitry region including a pixel region and a non-pixel region disposed around the pixel region; a photodiode disposed in the circuitry region; a trench portion extending from a top of the photodiode toward a bottom of the photodiode; a scattering portion disposed on the photodiode in the pixel region and structured to allow light entering the pixel region to scatter; a color filter disposed over the photodiode and the trench portion; and a light concentrating pattern disposed on the color filter and structured to direct the light toward the pixel region, and a refractive index of the scattering portion may be lower than a refractive index of the color filter and a refractive index of the light concentrating pattern.

### CROSS REFERENCE TO RELATED APPLICATION

This patent document claims the priority and benefits of Korean Patent Application No. 10-2024-0089431, filed Jul. 8, 2024, which is incorporated by reference in its entirety as part of the disclosure of this patent document.

### TECHNICAL FIELD

Various embodiments of the disclosed technology relate to image sensing devices and methods for manufacturing the same.

### BACKGROUND

With the development of the information and communication technologies and the digitalization of image information, image sensors are being used in various electrical devices, such as digital cameras, camcorders, mobile phones, personal communication systems (PCSs), game machines, surveillance and security cameras and medical micro-cameras. In general, an image sensor includes a pixel region that includes photodiodes and a peripheral circuit region. A unit pixel may include a photodiode and a transfer transistor. The transfer transistor may be disposed between a photodiode and a floating diffusion region to transfer the charge generated by the photodiode to the floating diffusion region.

### SUMMARY

The disclosed technology can be implemented in some embodiments to provide an image sensing device capable of improving a quantum efficiency of an infrared sensor.

The disclosed technology can be implemented in some embodiments to provide an image sensing device having an improved property change of a color filter.

The disclosed technology can be implemented in some embodiments to provide a method for manufacturing an image sensing device capable of improving a quantum efficiency of an infrared sensor.

The disclosed technology can be implemented in some embodiments to provide a method for manufacturing an image sensing device having an improved property change of a color filter.

In an embodiment, an image sensing device may include a circuitry region that includes a pixel region and a non-pixel region disposed around the pixel region; a photodiode disposed in the circuitry region; a trench portion extending from a top of the photodiode toward a bottom of the photodiode; a scattering portion disposed on the photodiode in the pixel region and structured to allow light entering the pixel region to scatter; a color filter disposed over the photodiode and the trench portion; and a light concentrating pattern disposed on the color filter and structured to direct the light toward the pixel region, and a refractive index of the scattering portion may be lower than a refractive index of the color filter and a refractive index of the light concentrating pattern.

In another embodiment, an image sensing device may include a circuitry region including a pixel region and a non-pixel region disposed around the pixel region; a photodiode disposed in the circuitry region; a color filter disposed on the photodiode; a scattering portion disposed inside the color filter in the pixel region and structured to allow light entering the pixel region to scatter; and a light concentrating pattern disposed on the color filter and the scattering portion and structured to direct the light toward the pixel region, and a refractive index of the scattering portion may be lower than a refractive index of the color filter and a refractive index of the light concentrating pattern.

In another embodiment, a method for manufacturing an image sensing device may include: forming a photodiode layer on a circuitry region that includes a pixel region and a non-pixel region disposed around the pixel region; forming a first trench portion in the non-pixel region and a second trench portion in the pixel region inside the photodiode by etching part of the photodiode layer; forming an anti-reflection layer on the photodiode; forming a first grid portion on the anti-reflection layer in the non-pixel region; forming a carbon layer and a stopper layer on the first grid portion and the anti-reflection layer; etching the carbon layer and the stopper layer to form an etched carbon layer and an etched stopper layer; forming a first insulation layer on the etched carbon layer and the etched stopper layer; and oxidizing the carbon layer and forming a scattering portion in the pixel region and a second grid portion in the non-pixel region.

In some embodiments, a first trench portion may be disposed in a first groove on a photodiode in a non-pixel region and a second trench portion may be disposed in a second groove on the photodiode in a pixel region. The first trench portion may totally reflect light that travels toward a side surface of the photodiode, and the second trench portion may scatter light incident on the photodiode. Both of the first and the second trench portions may improve the path of light within the photodiode, thereby improving the quantum efficiency (QE) of the photodiode.

In some embodiments, a grid portion may be disposed at the boundary (a non-pixel region) between neighboring pixels. The grid portion can either absorb or totally reflect light that is incident on the non-pixel region. As a result, color mixing or optical crosstalk between neighboring pixels may be prevented.

In some embodiments, a scattering portion may be disposed in the pixel region. The scattering portion may include a material with a lower refractive index than those of the materials of the light concentrating pattern on the upper surface and the color filter. Light incident on the scattering portion is scattered, increasing the path of light entering through the light concentrating pattern. As a result, the quantum efficiency (QE) of the photodiode may be improved.

In some embodiments, the scattering portion is disposed in the pixel region, and the scattering portion may be positioned inside the color filter in a planar view. Since light entering through the light concentrating pattern is scattered by the scattering portion, it is possible to prevent the incident light from being focused in the color filter. As a result, it is possible to improve the performance of the color filter.

### BRIEF DESCRIPTION OF THE DRAWINGS

FIG. 1 is a block diagram illustrating an imaging system based on an embodiment of the disclosed technology.

FIG. 2 is a block diagram illustrating an example of an image sensing device illustrated in FIG. 1.

FIG. 3 is a plan view illustrating an example of a pixel array illustrated in FIG. 2.

FIG. 4 is a cross-sectional view taken along line A-A′ of FIG. 3.

FIG. 5 is a cross-sectional view of a pixel array of an image sensing device implemented based on a comparative example.

FIG. 6 is a schematic view of a pixel array of an image sensing device implemented based on an embodiment of the disclosed technology.

FIGS. 7 to 20 are cross-sectional views illustrating various operations of a method for manufacturing an image sensing device based on an embodiment of the disclosed technology.

FIG. 21 is a cross-sectional view of a pixel array of an image sensing device based on another embodiment of the disclosed technology.

FIG. 22 is a cross-sectional view of a pixel array of an image sensing device based on another embodiment of the disclosed technology.

FIG. 23 is a cross-sectional view of a pixel array of an image sensing device based on another embodiment of the disclosed technology.

FIG. 24 is a cross-sectional view of a pixel array of an image sensing device based on another embodiment of the disclosed technology.

FIG. 25 is a cross-sectional view of a pixel array of an image sensing device based on another embodiment of the disclosed technology.

FIG. 26 is a cross-sectional view of a pixel array of an image sensing device based on another embodiment of the disclosed technology.

FIG. 27 is a cross-sectional view of a pixel array of an image sensing device based on another embodiment of the disclosed technology.

FIG. 28 is a cross-sectional view of a pixel array of an image sensing device based on another embodiment of the disclosed technology.

FIG. 29 is a cross-sectional view of a pixel array of an image sensing device based on another embodiment of the disclosed technology.

FIG. 30 is a cross-sectional view of a pixel array of an image sensing device based on another embodiment of the disclosed technology.

### DETAILED DESCRIPTION

Hereinafter, example embodiments will be described with reference to the accompanying drawings.

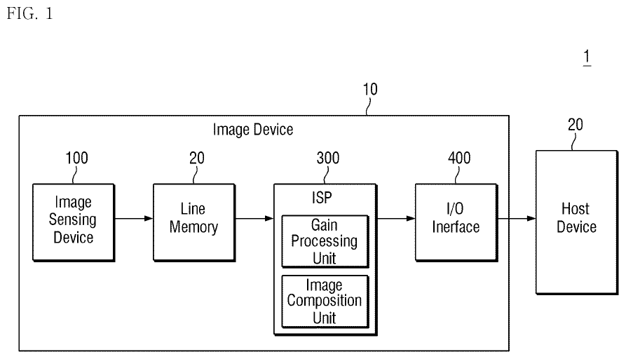

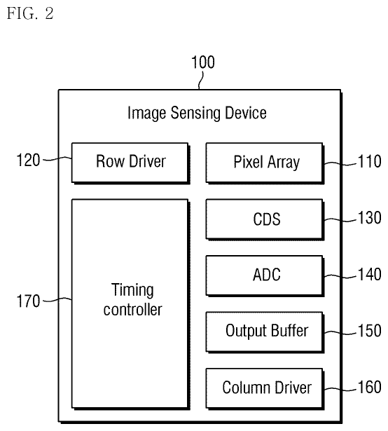

Like reference numerals refer to like elements throughout. Additionally, in the drawings, the thicknesses, proportions, and dimensions of components may be exaggerated for the purpose of effective explanation. FIG. 1 is a block diagram illustrating an imaging system based on an embodiment of the disclosed technology. FIG. 2 is a block diagram illustrating an example of an image sensing device illustrated in FIG. 1.

Referring to FIG. 1, in some embodiments, the imaging system 1 may refer to a device such as a digital still camera for capturing still images, a digital video camera for recording videos, or a device for detecting motion. For example, the imaging device 10 may be implemented as a Digital Single Lens Reflex (DSLR) camera, a mirrorless camera, or a smartphone, and others, but is not limited thereto. The imaging device 10 may include a device including a lens and an image sensor to capture a target object and create an image of the target object.

The imaging system 1 may include an imaging device 10 and a host device 20.

The imaging device 10 may include an image sensing device 100, a line memory 200, an image signal processor (ISP) 300, and an input/output (I/O) interface 400.

The image sensing device 100 may be a complementary metal oxide semiconductor image sensor (CMOS image sensor or CIS) for converting an optical signal into an electrical signal. The image sensing device 100 may control overall operations such as on/off operations, operation mode, operation timing, sensitivity, etc. by the ISP 300. The image sensing device 100 may transmit, to the line memory 200, image data obtained by converting the optical signal into the electrical signal under the control of the ISP 300.

Referring to FIG. 2, the image sensing device 100 may include a pixel array 110, a row driver 120, a correlated double sampler (CDS) 130, an analog-digital converter (ADC) 140, an output buffer 150, a column driver 160, and a timing controller 170. The components of the image sensing device 100 illustrated in FIG. 2 are discussed by way of example only, and at least some components may be added or omitted as needed.

The pixel array 110 may include a plurality of imaging pixels arranged in rows and columns. In an embodiment, the plurality of imaging pixels can be arranged in a two dimensional pixel array including rows and columns. In another example, the plurality of imaging pixels can be arranged in a three dimensional pixel array. The plurality of imaging pixels may convert an optical signal into an electrical signal on a unit pixel basis or a pixel group basis, where the imaging pixels in a pixel group share at least certain internal circuitry. The pixel array 110 may receive pixel control signals, including a row selection signal, a pixel reset signal and a transmission signal, from the row driver 120. Upon receiving the pixel control signals, corresponding pixels in the pixel array 110 may be activated to perform the operations corresponding to the row selection signal, the pixel reset signal, and the transmission signal. Each of the imaging pixels may generate photocharges corresponding to the intensity of incident light (or luminous intensity), may generate an electrical signal corresponding to the amount of photocharges, thereby sensing the incident light. For convenience of description, the imaging pixel may also be referred to as a pixel.

The row driver 120 may activate the pixel array 110 to perform certain operations on the imaging pixels in the corresponding row based on commands and control signals provided by the timing controller 170. In an embodiment, the row driver 120 may select at least one pixel arranged in at least one row of the pixel array 110. The row driver 120 may generate a row selection signal to select at least one row among the plurality of rows. The row driver 120 may sequentially enable the pixel reset signal and the transmission signal for the pixels corresponding to at least one selected row. Thus, a reference signal and an image signal, which are analog signals generated by each of the pixels of the selected row, may be sequentially transferred to the CDS 130. The reference signal may be an electrical signal that is provided to the CDS 130 when a sensing node of a pixel (e.g., floating diffusion node) is reset, and the image signal may be an electrical signal that is provided to the CDS 130 when photocharges generated by the imaging pixel are accumulated in the sensing node. The reference signal indicating unique reset noise of each pixel and the image signal indicating the intensity of incident light may be referred to as a pixel signal.

The image sensing device 100 may use the correlated double sampling (CDS) to remove undesired offset values of pixels known as the fixed pattern noise by sampling a pixel signal twice to remove the difference between these two samples. In an embodiment, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

The CDS 130 may transfer the reference signal and the image signal of each of the columns as a correlate double sampling signal to the ADC 140 based on control signals from the timing controller 170.

The ADC 140 may convert analog CDS signals output from the CDS 130 with respect to each column into digital signals, and output image data. In an embodiment, the ADC 140 may convert the correlate double sampling signal generated by the CDS 130 for each of the columns into a digital signal, and output the digital signal.

The ADC 140 may include a plurality of column counters. Each column of the pixel array 110 is coupled to a column counter, and image data can be generated by converting the correlate double sampling signals corresponding to each column into digital signals using the column counter. In another embodiment of the disclosed technology, the ADC 140 may include a global counter to convert the correlate double sampling signals corresponding to each of the columns into digital signals using a global code provided from the global counter.

The output buffer 150 may temporarily store the column-based image data provided from the ADC 140 to output the image data. The output buffer 150 may temporarily store image data output from the ADC 140 based on the control signal of the timing controller 170. The output buffer 150 may serve as an interface to compensate for data rate differences (or data processing speed differences) between the image sensing device 100 and other devices.

The column driver 160 may select a column of the output buffer 150 based on a control signal from the timing controller 170, and sequentially output the image data, which are temporarily stored in the selected column of the output buffer 150. In an embodiment, the column driver 160 may receive an address signal from the timing controller 170, generate a column selection signal based on the address signal and select a column of the output buffer 150, thereby outputting the image data from the selected column of the output buffer 150.

The timing controller 170 may control at least one among the row driver 120, the CDS 130, the ADC 140, the output buffer 150 and the column driver 160.

The timing controller 170 may provide at least one among the row driver 120, the CDS 130, the ADC 140, the output buffer 150 and the column driver 160 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

Referring back to FIG. 1, the line memory 200 may include a volatile memory (e.g., DRAM, SRAM, etc.) and/or a non-volatile memory (e.g., a flash memory). The line memory 200 may have a capacity capable of storing image data corresponding to a predetermined number of lines. In this case, the line may refer to a row of the pixel array 110, and the predetermined number of lines may be less than a total number of rows of the pixel array 120. Therefore, the line memory 200 may be a line memory capable of storing image data corresponding to some rows (or some lines) of the pixel array 110, rather than a frame memory capable of storing image data corresponding to a frame captured once by the pixel array 110. In another embodiment, the line memory 200 may also be replaced with a frame memory.

The line memory 200 may receive image data from the image sensing device 100, may store the received image data, and may transmit the stored image data to the ISP 300 based on the control of the ISP 300.

The ISP 300 may perform image processing of the image data stored in the line memory 200. The ISP 300 may reduce noise of image data, and may perform various kinds of image signal processing such as gamma correction, color filter array interpolation, color matrix, color correction, color enhancement, lens distortion correction, etc. for image-quality improvement of the image data. In addition, the ISP 300 may compress image data that has been created by execution of image signal processing for image-quality improvement, such that the ISP 300 can create an image file using the compressed image data. Alternatively, the ISP 300 may recover image data from the image file. In this case, the scheme for compressing such image data may be a reversible format or an irreversible format. As a representative example of such compression format, in the case of using a still image, Joint Photographic Experts Group (JPEG) format, JPEG 2000 format, or the like can be used. In addition, in the case of using moving images, a plurality of frames can be compressed according to Moving Picture Experts Group (MPEG) standards such that moving image files can be created. For example, the image files may be created according to Exchangeable image file format (Exif) standards.

In order to generate the HDR image, the ISP 300 may include a gain processing unit 310, and an image composition unit 320.

The gain processing unit 310 may determine a gain to be calculated with (to be multiplied by) image data. The gain processing unit 310 may determine a gain according to a difference in the conversion gain between the high conversion gain (HCG) mode and the low conversion gain (LCG) mode, and may provide the determined gain to the image composition unit 320. The gain may be experimentally determined in advance according to the difference in the conversion gain, and may be stored in the gain processing unit 310. In an embodiment, the gain processing unit 310 may store the experimentally determined gain in a table according to a size of the image data, such that the gain processing unit 310 may acquire a necessary gain corresponding to the image data by referring to content stored in the table.

Each pixel of the pixel array 110 may operate in one mode among the HCG mode and LCG mode, and the mode of each pixel may be determined according to the intensity (or illuminance) of light that is incident on each pixel. The HCG mode means a mode in which the pixel has a relatively greater conversion gain, and the LCG mode means a mode in which the pixel has relatively smaller conversion gain. At this time, the conversion gain may mean a ratio of a voltage level of the pixel signal, of which the photocharges are converted, to the amount of photocharges generated in the pixel. The amount of photocharges generated in the pixel is proportionate to illuminance with respect to each pixel, and thus, the HCG mode may mean a mode having a relatively greater change of the pixel signal according to the change of the illuminance, and the LCG mode may mean a mode having a relatively smaller change of the pixel signal according to the change of the illuminance.

That is, in the HCG mode and the LCG mode, slopes of the pixel signal with respect to the illuminance are different from each other. The gain may be a correction value to make a slope of the pixel signal (or image data) with respect to the illuminance of the pixel operating in the HCG mode, and a slope of the pixel signal (or image data) with respect to the illuminance of the pixel operating in the LCG mode be equal to each other.

The image composition unit 320 may synthesize HDR image corresponding to a high dynamic range by using the image data of the pixel operating in the HCG mode and/or the image data of the pixel operating in the LCG mode.

In an embodiment, the image composition unit 320 may perform a calculation, using the gain provided from the gain processing unit 310, on the image data of the pixel operating in the HCG mode and/or the image data of the other pixel operating in the LCG mode, and may allow the calculated image data to be formed as the HDR image.

The ISP 300 may transmit image data (e.g., HDR image data) obtained by such image signal processing to the I/O interface 400.

In another embodiment, the gain processing unit 310 and the image composition unit 320 that are used to generate the HDR image may also be included in the image sensing device 100, not in the ISP 300.

The I/O interface 400 may perform a communication with the host device 20, and may transmit the image signal processed (ISP) image data to the host device 20. In an embodiment, the I/O interface 400 may be implemented as, for example, a mobile industry processor interface (MIPI), but the range is not limited thereto.

The host device 20 may be a processor (e.g., an application processor) for processing the ISP image data received from the imaging device 10, a memory (e.g., a non-volatile memory) for storing the ISP image data, or a display device (e.g., a liquid crystal display (LCD)) for visually displaying the ISP image data.

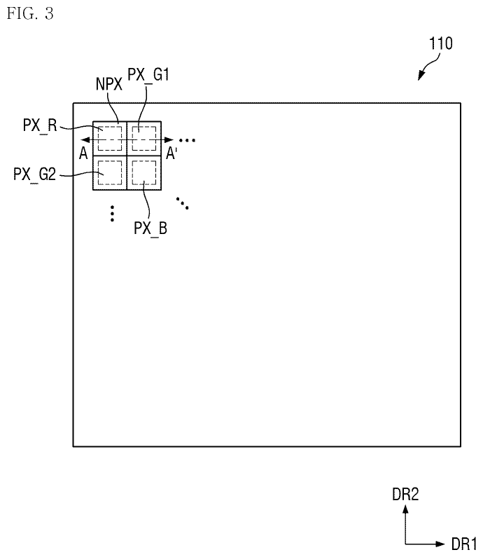

FIG. 3 is a plan view illustrating an example of a pixel array illustrated in FIG. 2.

Referring to FIG. 3, the pixel array 110 based on an embodiment may include a plurality of pixels. The plurality of pixels may include a first pixel, a second pixel, a third pixel, and a fourth pixel. Each pixel may include pixel regions PX_R, PX_G1, PX_G2, and PX_B, and a non-pixel region NPX. The first pixel may be a red pixel which receives red light, the second pixel may be a green pixel which receives green light, the third pixel may be a green pixel which receives green light, and the fourth pixel may be a blue pixel which receives blue light. During the daytime, each pixel may receive light in the wavelength range of a visible ray in correspondence with the wavelength range. For example, the first pixel, the second pixel, the third pixel, and the fourth pixel may further receive light in the wavelength range of the infrared light. That is, peak wavelengths of the first pixel may be a red wavelength and an infrared wavelength, peak wavelengths of the second pixel and the third pixel may be a green wavelength and the infrared wavelength, and peak wavelengths of the fourth pixel may be a blue wavelength and the infrared wavelength. That is, during the daytime, there is little light within the wavelength range of the visible ray, and therefore, each pixel may receive light within the infrared wavelength range per region. The plurality of pixels may be repeatedly disposed along a first direction DR1 and a second direction DR2, but are not limited thereto. Considering a peak wavelength range of the light to be received, a color filter may be disposed in each of the plurality of pixels. For example, a red color filter is disposed in the first pixel, a green color filter is disposed in the second and the third pixels, and a blue color filter is disposed in the fourth pixel.

In some embodiments, the plurality of pixels may further include a fifth pixel which receives white light, but the disclosed technology is not limited thereto.

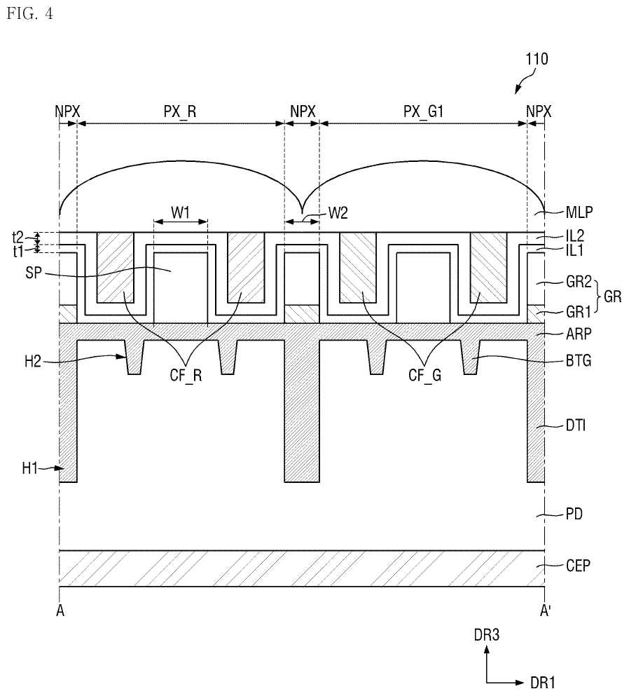

FIG. 4 is a cross-sectional view taken along line A-A′ of FIG. 3. In FIG. 4, a cross-sectional view of the pixel array of the first and the second pixels is illustrated.

Referring to FIG. 4, the pixel array 110 based on an embodiment may include circuitry CEP, a photosensing device or photodetector such as a photodiode PD on the circuitry CEP, a first trench portion DTI and a second trench portion BTG inside the photodiode PD, an anti-reflection layer ARP on the photodiode PD, a scattering portion SP on the anti-reflection lay ARP in the pixel regions PX_R and PX_G1, a grid portion GR in the non-pixel region NPX, insulation layers IL1 and IL2 on the scattering portion SP and the grid portion GR, color filters CF_R and CF_G on the insulation layers IL1 and IL2, and a light concentrating pattern MLP on the color filters CF_R and CF_G. In some embodiments of the disclosed technology, the light concentrating pattern MLP may include microlenses. In some embodiments of the disclosed technology, the scattering portion SP may include a structure with physical properties that are designed to cause light entering the pixel regions PX_R and PX_G1 to scatter within the scattering portion SP.

The circuitry CEP is disposed on the bottom surface of the photodiode PD, and may include transistors, a wiring layer, and an interlayer insulation layer. The transistors may include an overflow transistor, a transfer transistor, a reset transistor, a driving transistor, and a selection transistor, all of which are formed on the bottom surface of the photodiode PD.

The photodiode PD may include a single-crystalline silicon wafer or an epitaxially grown single-crystalline silicon layer. The photodiode PD may have a high refractive index. For example, the refractive index of the photodiode PD may be about 2.5 or more, but is not limited thereto. For example, the refractive index of the photodiode PD may be about 4 to 6, but is not limited thereto.

The forming of the photodiodes PD may include injecting P-type ions and N-type ions by using an ion injecting process. The P-type ions may include boron (B) ions, and N-type ions may include phosphorous (P) ions and/or arsenic (As) ions. The photodiode PD serves to convert the optical signals into the electric signals by receiving the incident light. The photodiode PD may refer to a portion which corresponds to the pixel regions PX_R and PX_G1 only, but is not limited thereto.

In the photodiode PD, a first groove H1 and a second groove H2 may be formed. The first groove H1 and the second groove H2 may be formed by indenting the photodiode PD in a thickness direction. A depth of the first groove H1 may be greater than a depth of the second groove H2. The first groove H1 may be formed in the non-pixel region NPX, and the second groove H2 may be formed in the pixel regions PX_R and PX_G1. In the first groove H1, the first trench portion DTI may be formed, and in the second groove H2, the second trench portion BTG (back side trench guide) may be formed. The first trench portion DT1 may be formed through a deep trench process. The second groove H2 may be provided one or two in number in one pixel region PX_R and PX_G1, and may be provided three in number therein. Therefore, the second trench portion BTG may be provided one, two or three or more in number in one pixel region PX_R and PX_G1. The first trench portion DTI and the second trench portion BTG may include the same material. For example, the first trench portion DTI and the second trench portion BTG may include an insulation material. For example, an example of the insulation material is hafnium oxide (HfO2), or silicon oxide (SiO2), but is not limited thereto. The refractive index of the first trench portion DTI and the second trench portion BTG may be, for example, about 1.4 to 2.0, but is not limited thereto. The first trench portion DTI serves to totally reflect light incident on the first trench portion DTI to the photodiode PD, and the second trench portion BTG serves to scatter light incident from the light concentrating pattern MLP. The first trench portion DTI and the second trench portion BTG may serve to increase a path of the light by totally reflecting the light to the photodiode PD or scattering the light. Because of this, the trench portion may serve to improve a quantum efficiency of the photodiode PD.

The anti-reflection layer ARP may be disposed on the photodiode PD and the trench portions DTI and BTG. The anti-reflection layer ARP may be in direct contact with the photodiode PD and the trench portions DTI and BTG. The anti-reflection layer ARP may include the same as the material of the trench portions DTI and BTG. The anti-reflection layer ARP may be formed in the same manufacture process as the manufacture process of the trench portions DTI and BTG, and may be integrally connected with the trench portions DTI and BTG. The anti-reflection layer ARP may serve to reduce light reflection or to prevent the light incident on the light concentrating pattern MLP from being totally reflected in the photodiode PD. To this end, the anti-reflection layer ARP may have a refractive index between a refractive index of the color filters CF_R and CF_G and a refractive index of the photodiode PD, or between a refractive index of the scattering portion SP and a refractive index of the photodiode PD, but is not limited thereto. For example, the refractive index of the anti-reflection layer ARP may be about 1.4 to 2.0, but is not limited thereto. The anti-reflection layer ARP may be disposed throughout the pixel regions PX_R and PX_G1, and the non-pixel region NPX.

The grid portion GR may be disposed on the anti-reflection layer ARP. The grid portion GR may be disposed in the non-pixel region NPX. The grid portion GR may include a first grid portion GR1 and a second grid portion GR2 on the first grid portion GR1. The first grid portion GR1 may include a metal. The first grid portion GR1 is disposed in the non-pixel region NPX, and therefore, may absorb light incident on the first grid portion GR1. The first grid portion GR1 may prevent color mixing between the neighboring pixel regions PX_R and PX_G1. The second grid portion GR2 may include a low refractive layer. For example, the second grid portion GR2 may include a low refractive insulation material, or an air structure. In an embodiment, the second grid portion GR2 may include an air structure. The second grid portion GR2 may be disposed in the non-pixel region NPX, and may serve to totally reflect the light incident on the second grid portion GR2. The second grid portion GR2 may prevent color mixing between the neighboring pixel regions PX_R and PX_G1. A thickness of the second grid portion GR2 may be greater than a thickness of the first grid portion GR2, but is not limited thereto.

The scattering portion SP may be disposed on the anti-reflection layer ARP in the pixel regions PX_R and PX_G1. The scattering portion SP may include a low refractive layer. For example, the scattering portion SP may include an air structure (e.g., a structure including air). A width W2 of the scattering portion SP may be greater than a width W1 of the second grid portion GR2, but is not limited thereto. The scattering portion SP may be disposed at a center of the pixel regions PX_R and PX_G1. For example, the scattering portion SP may be disposed between two second trench portions BTG. The scattering portion SP may not overlap the second trench portion BTG. In some embodiments, the scattering portion SP may overlap the second trench portion BTG. The scattering portion SP may serve to scatter light incident on the light concentrating pattern MLP. The scattering portion SP scatters light incident on the light concentrating pattern MLP, thereby increasing a path of the light incident on the light concentrating pattern MLP, and improving a quantum efficiency of the photodiode PD. The insulation layers IL1 and IL2 may be disposed on the scattering portion SP and the grid portion GR. The insulation layers IL1 and IL2 may include a first insulation layer IL1, and a second insulation layer IL2 on the first insulation layer IL1. The first insulation layer IL1 may include an insulation material. For example, the first insulation layer IL1 may include silicon oxide (SiO2), but is not limited thereto. The second insulation layer IL2 may include an insulation material. For example, the second insulation layer IL2 may include silicon oxide (SiO2), but is not limited thereto. For example, the second insulation layer IL2 may include silicon oxide SiO2, but is not limited thereto. However, a thickness t1 of the first insulation layer IL1 may be smaller than a thickness t2 of the second insulation layer IL2, and a value of a free volume of the first insulation layer IL1 may be greater than a value of a free volume of the second insulation layer IL2. The first insulation layer IL1 is formed in a region in which the scattering portion SP and the second grid portion GR2 are to be formed in a process of forming the scattering portion SP and the second grid portion GR2 having the air structure. Oxygen is irradiated onto the first insulating layer IL1, and the irradiated oxygen passes through the first insulating layer IL1 and oxidizes a carbon layer filling the region where the scattering portion SP and the second grid portion GR2 are to be formed. The oxidized carbon layer becomes carbon dioxide and is removed to form the scattering portion SP and the second grid portion GR2 having the air structure. Therefore, the first insulating layer IL1 must be a multi-porous layer, and for this purpose, the free volume value of the first insulating layer IL1 must be higher than that of the second insulating layer IL2. Additionally, in order to allow oxygen to pass through, it is desirable that a thickness of the first insulating layer IL1 be smaller than that of the second insulating layer IL2.

The color filters CF_R and CF_G may be disposed on the second insulation layer IL2. The first color filter CF_R may receive light in a red wavelength range and an ultraviolet wavelength range, and block light in the remaining wavelength ranges, and the second color filter CF_G may receive light in a green wavelength range and an ultraviolet wavelength range, and block light in the remaining wavelength ranges. Surfaces of the color filters CF_R and CF_G may be positioned to be collinear with a surface of the second insulating layer IL2, but are not limited thereto.

The light concentrating pattern MLP may be disposed on the color filters CF_R and CF_G and the second insulating layer IL2. The light concentrating pattern MLP may serve to direct incoming light toward the pixel regions PX_R and PX_G1. To this end, the light concentrating pattern MLP may have a shape of a convex lens that is convex upward, and may be formed of a material with a great difference in the refractive index compared to the refractive index of the external air. For example, the refractive index of the light concentrating pattern MLP can be, but is not limited to, about 1.5 to about 1.7. The light concentrating pattern MLP may be arranged continuously in the pixel regions PX_R and PX_G1 and the non-pixel region NPX, as shown in FIG. 4, and may be formed such that an end of the convex lens shape is positioned in the center of the pixel regions PX_R and PX_G1, but is not limited to. The light concentrating pattern MLP may be disconnected in the non-pixel region NPX, in which case the plurality of the light concentrating patterns MLP may be positioned in each of the pixel regions PX_R and PX_G1.

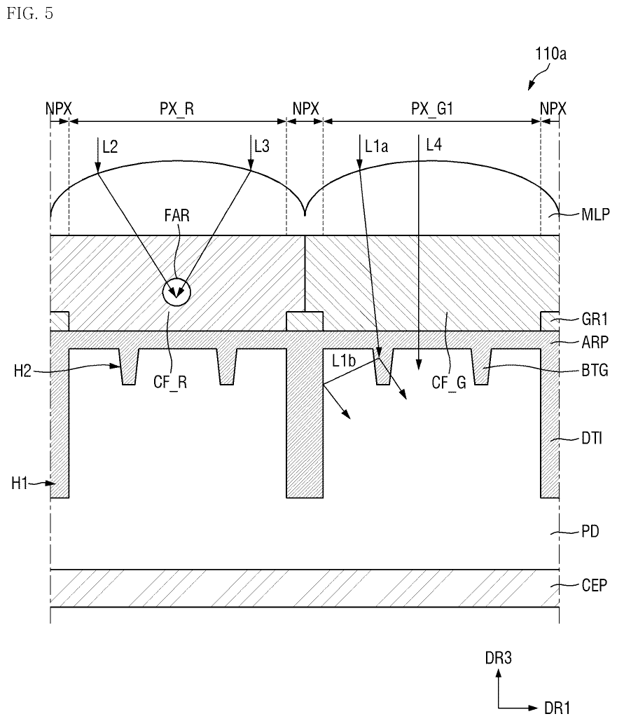

FIG. 5 is a cross-sectional view of a pixel array of the image sensing device implemented based on a comparative example.

Referring to FIGS. 4 and 5, in a pixel array of the image sensing device implemented based on a comparative example, the scattering portion SP and the second grid portion GR2, which have been described referring to FIG. 4 are omitted. As illustrated in FIG. 5, a first light ray L1a incident through the light concentrating pattern MLP may pass through the color filter CF_G and be incident on the second trench portion BTG. The first light ray L1a incident on the second trench portion BTG may be scattered. That is, the second trench portion BTG may scatter the first light ray L1a incident through the light concentrating pattern MLP and increase the path of light. In addition, the first light ray L1a incident on the first trench portion DTI may be totally reflected by the first trench portion DTI. That is, the first trench portion DTI may totally reflect the incident first light ray L1a and increase the path of the light. The first light rays L1a and L1b may be the light in the infrared wavelength range.

The second light L2 and the third light L3 incident on the light concentrating pattern MLP may be refracted by the light concentrating pattern MLP, and may be focused in the first color filter CF_R. (Refer to a focusing region FAR). In this case, a property change of the first color filter CF_R may occur. Though not illustrated, the color filter of the second pixel which has been described referring to FIG. 3 (or a green color filter) and the color filter of the third pixel (or a green color filter) must have the same property, however, if the property change occurs due to the above-mentioned focusing, color purity, and color reproducibility, etc. may be reduced. The second and third light rays L2 and L3 may be light rays in the infrared wavelength range.

In case of a fourth light ray L4, which has passed through the light concentrating pattern MLP and the color filter CF_G, is incident directly into the photodiode PD, and the path of the light ray is short, the quantum efficiency of the photodiode PD may be very low. The fourth light ray L4 may be in the infrared wavelength range.

In particular, the photodiode PD may have a very low quantum efficiency of the light ray in the infrared wavelength range (or the infrared light). On contrary, the photodiode PD may have the quantum efficiency of about 70 to 80% with respect to the light ray in the visible light wavelength range. For example, the photodiode PD may have the quantum efficiency of about 30% to 40%, which is very low, with respect to the light ray in the infrared wavelength range (or the infrared light).

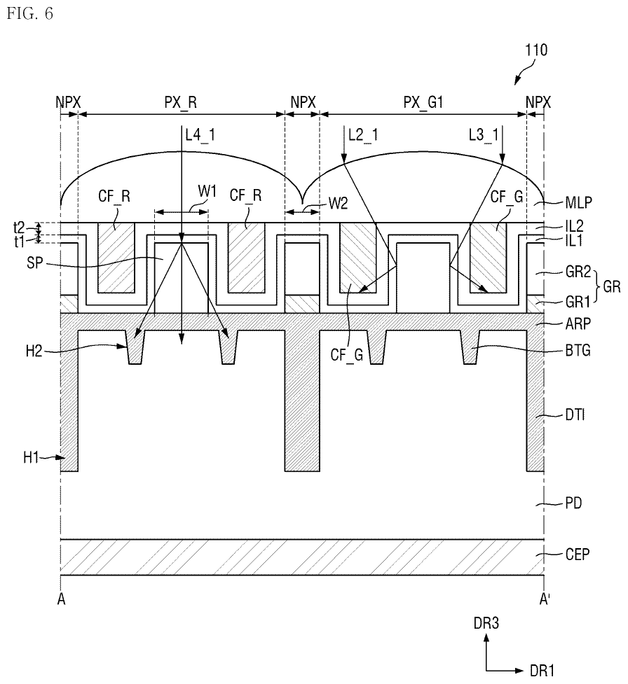

FIG. 6 is a schematic view of the pixel array of the image sensing device implemented based on an embodiment of the disclosed technology.

Referring to FIG. 6, the second light ray L2_1 and the third light ray L3_1 incident on the light concentrating pattern MLP may be refracted by the light concentrating pattern MLP and focused, but may be disposed on the scattering portion SP on the path of the light ray and be totally reflected by the scattering portion SP. Therefore, in case of the pixel array 110 implemented based on an embodiment, the scattering portion SP is disposed in the focusing region, thereby the property change of the color filters CF_R and CF_G may not occur.

In addition, the fourth light ray L4_1 may be scattered in the scattering portion SP. Because of this, the path of the light ray L4_1 incident on the scattering portion SP is increased, and the quantum efficiency of the photodiode PD may be increased. Each of the second light ray L2_1, the third light ray L3_1, and the fourth light ray L4_1 may be the light in the infrared wavelength range.

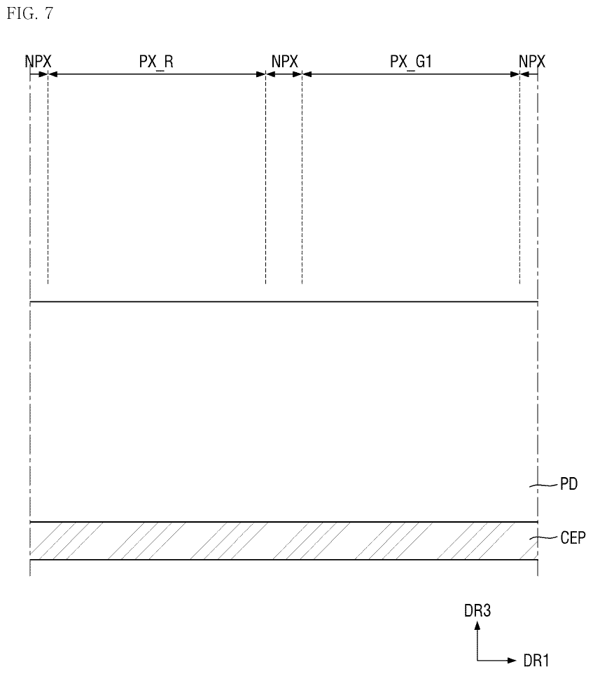

FIGS. 7 to 20 are cross-sectional views illustrating various operations of a method for manufacturing an image sensing device based on an embodiment of the disclosed technology.

Hereinafter, a method for manufacturing the pixel array 110 based on an embodiment will be described. In the course of describing the method for manufacturing the pixel array 110 below, redundant description with respect to the description provided referring to FIGS. 1 to 6 will be omitted.

FIGS. 7 to 20 are cross-sectional views at various stages of manufacture illustrating a method for manufacturing the image sensing device based on an embodiment.

Referring to FIGS. 4 to 7, the photodiode PD is formed on the circuitry CEP. The circuitry CEP is disposed is on the bottom surface of the photodiode PD, and includes transistors, a wiring layer, and an interlayer insulation layer. The transistors may include an overflow transistor, a transfer transistor, a reset transistor, a driving transistor, and a selection transistor, all of which may be formed below the bottom surface of the photodiode PD. The photodiode PD may include a single-crystalline silicon wafer or an epitaxially grown single-crystalline silicon layer. The photodiode PD may have a high refractive index. For example, the refractive index of the photodiode PD may be about 2.5 or more, but is not limited thereto. For example, the refractive ratio of the photodiode PD may be about 4 to 6, but is not limited thereto.

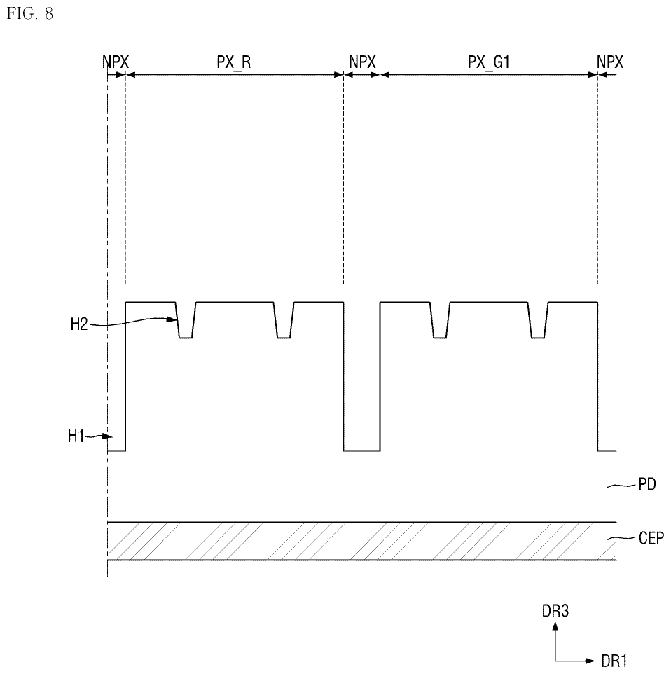

Next, referring to FIGS. 4 and 8, the first groove H1 and the second groove H2 are formed on the photodiode PD. Each of the first groove H1 and the second groove H2 may be formed by indenting the photodiode PD in a thickness direction. A depth of the first groove H1 may be greater than a depth of the second groove H2. The first groove H1 may be formed in the non-pixel region NPX, and the second groove H2 may be formed in the pixel regions PX_R and PX_G1.

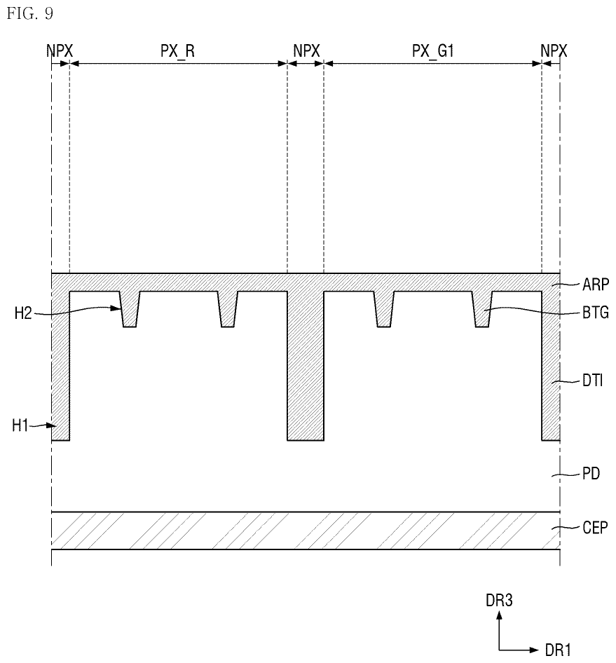

Next, referring to FIGS. 4 and 9, the first trench portion DTI is formed in the first groove H1, the second trench portion BTG is formed in the second groove H2, and the anti-reflection layer ARP is formed on the photodiode PD. The first trench portion DTI may serve to totally reflect the light incident on the first trench portion DTI to the photodiode PD, and the second trench portion BTG may serve to scatter the light incident on the light concentrating pattern MLP. Each of the first trench portion DTI and the second trench portion BTG may serve to increase the path of the light by totally reflecting the light to the photodiode PD, or scattering the light. Because of this, the first trench portion DTI and the second trench portion BTG may serve to improve the quantum efficiency of the photodiode PD.

The anti-reflection layer ARP may include the same material as the material of the first trench portion DTI and the second trench portion BTG. The anti-reflection layer ARP may be formed in the same process with the trench portions DTI and BTG, and may be integrally connected with the trench portions DTI and BTG. The anti-reflection layer ARP may serve to prevent the light incident on the light concentrating pattern MLP from being totally reflected in the photodiode PD. To this end, the anti-reflection layer ARP may have a refractive index between a refractive index of the color filters CF_R and CF_G and a refractive index of the photodiode PD, or between a refractive index of the scattering portion SP and a refractive index of the photodiode PD, but is not limited thereto. For example, the refractive index of the anti-reflection layer ARP may be about 1.4 to 2.0, but is not limited thereto. The anti-reflection layer ARP may be disposed throughout the pixel regions PX_R and PX_G1, and the non-pixel region NPX.

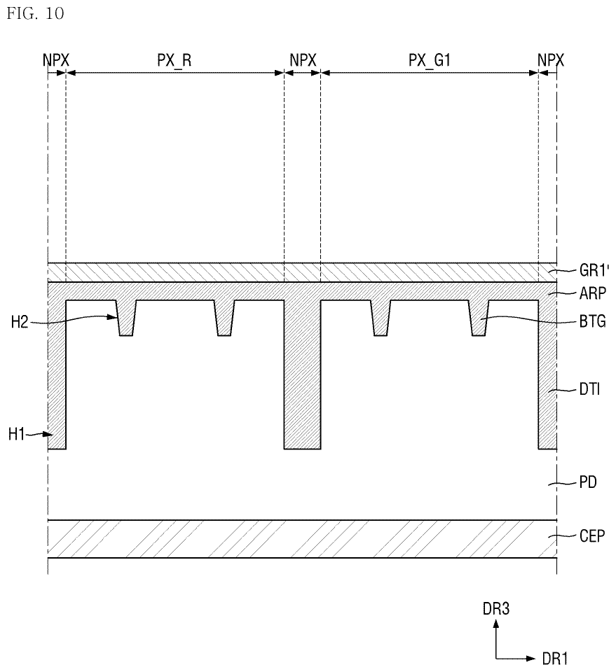

As illustrated in FIGS. 4 and 10, a first grid layer GR1′ is formed on the anti-reflection layer ARP. The first grid layer GR1′ may include a metal.

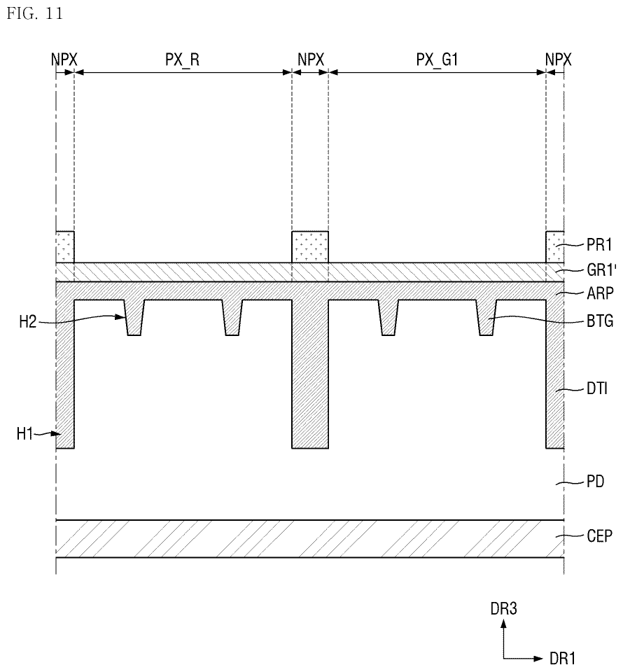

As illustrated in FIGS. 4 and 11, a first photoresist PR1 is formed on the first grid layer GR1′ in the non-pixel region NPX.

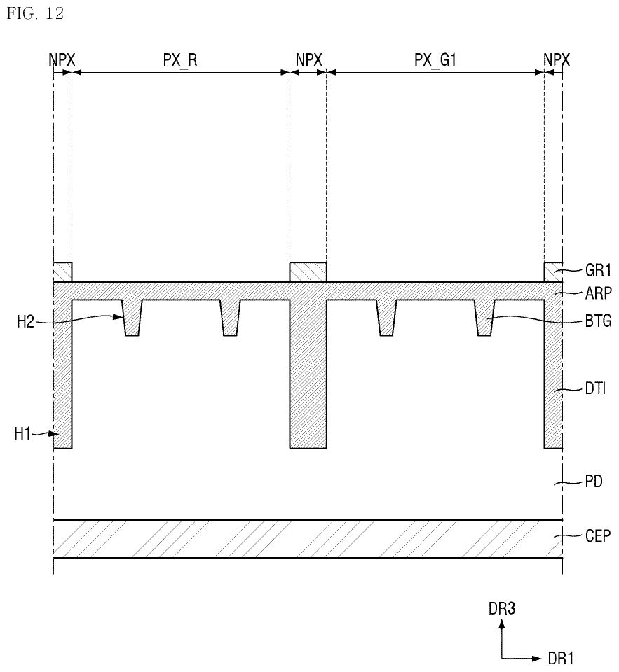

As illustrated in FIGS. 4 and 12, the first grid portion GR1 is formed using the first photoresist PR1 as a mask.

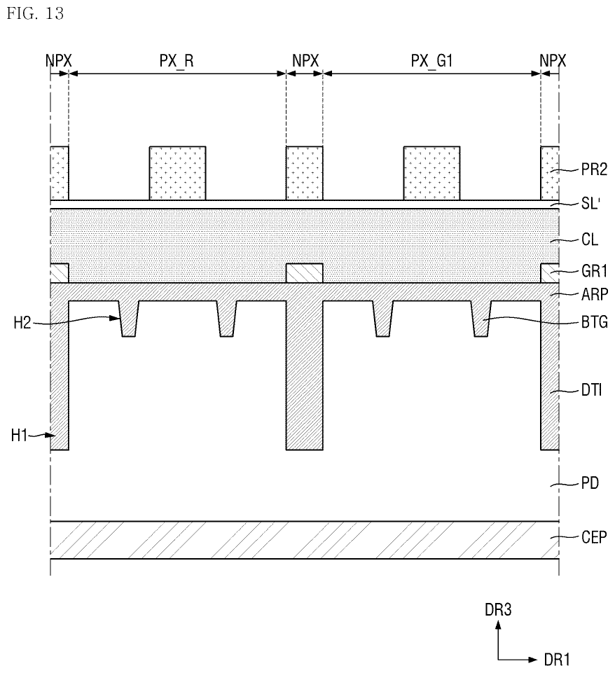

As illustrated in FIGS. 4 and 13, the carbon layer CL is formed on the first grid portion GR1, a stopper layer SL′ and a second photoresist PR2 are formed on the carbon layer CL. The second photoresist PR2 is formed in the centers of the pixel regions PX_R and PX_G1 and the non-pixel region NPX. The carbon layer CL may include carbon, and the stopper layer SL′ may include silicon nitride (SiNx).

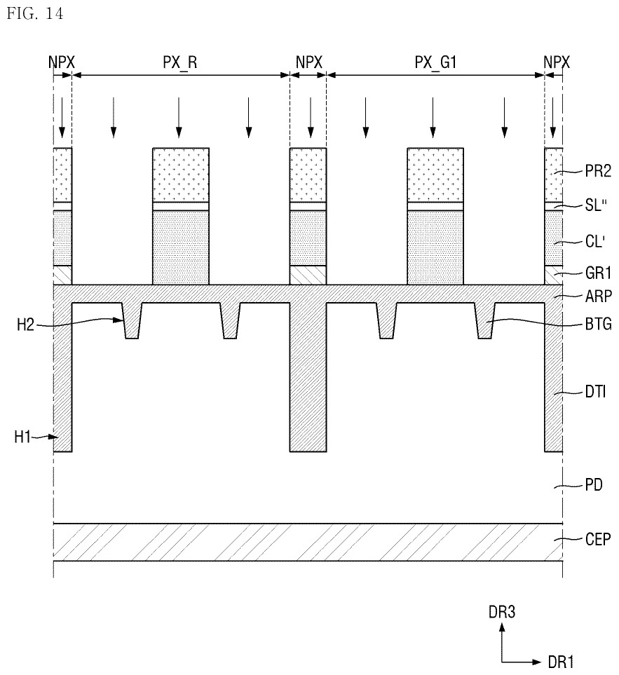

As illustrated in FIGS. 4 and 14, using the second photoresist PR2 as a mask, a stopper layer SL″ and a carbon layer CL′ are formed.

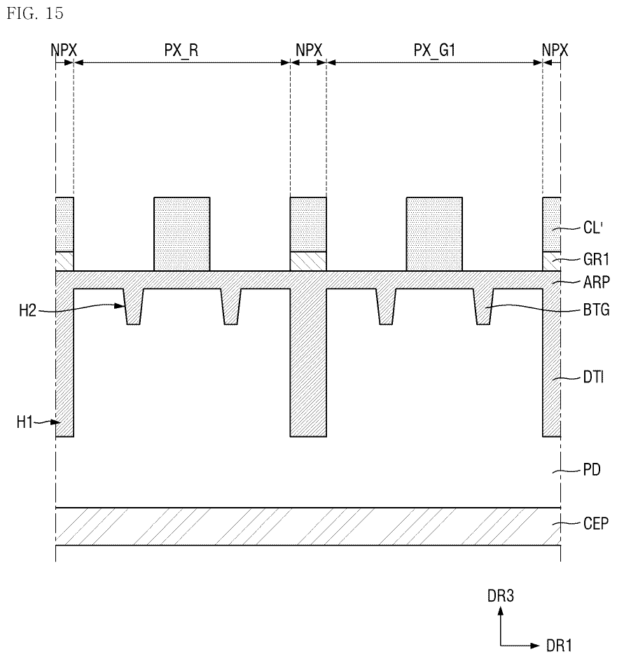

As illustrated in FIGS. 4 and 15, the second photoresist PR2 and the stopper layer SL″ are removed. The stopper layer SL″ is disposed on the carbon layer CL′ and may serve as an etching stopper with respect to an etchant or an etching gas in the course of removing the second photoresist PR2. It is preferable that the stopper layer SL″ is entirely removed as illustrated in FIG. 15.

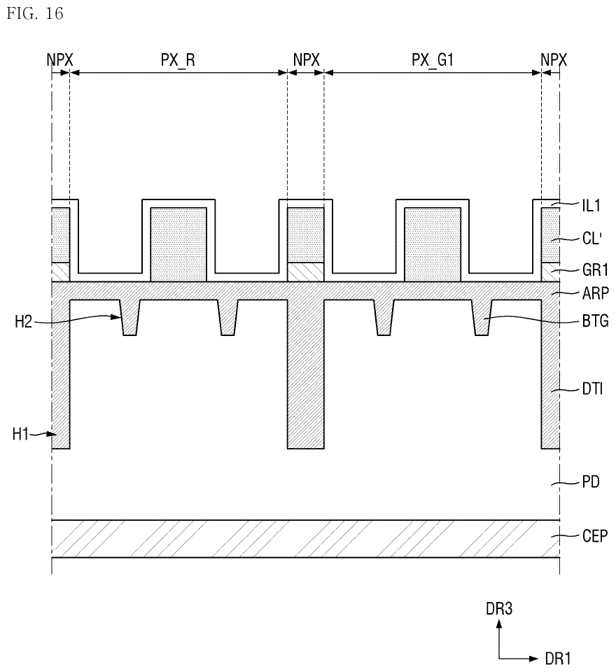

As illustrated in FIGS. 4 and 16, the first insulation layer IL1 is formed on an upper surface and a side surface of the carbon layer CL′ and on an upper surface of the exposed anti-reflection layer ARP. The first insulation layer IL1 may include silicon oxide (SiO2), but is not limited thereto. A thickness t1 of the first insulation layer IL1 may be smaller than a thickness t2 of the second insulation layer IL2, and a value of a free volume of the first insulation layer IL1 may be greater than a value of a free volume of the second insulation layer IL2.

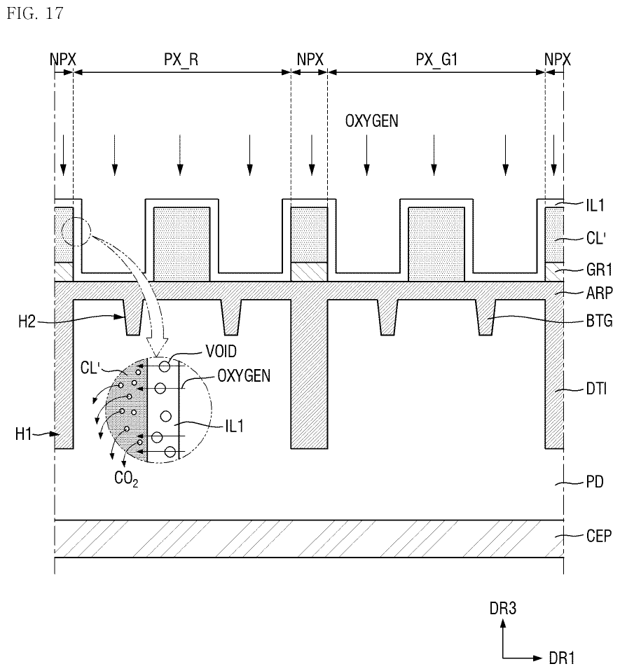

As illustrated in FIGS. 4 and 17, the carbon layer CL′ is oxidized using oxygen. Oxygen passes through a void (or a pore) positioned inside the first insulating layer IL1 and oxidizes the carbon layer CL′ to generate carbon dioxide (CO2). When the carbon layer CL′ is oxidized, the air structure may remain in a region in which the carbon layer CL′ has been formed.

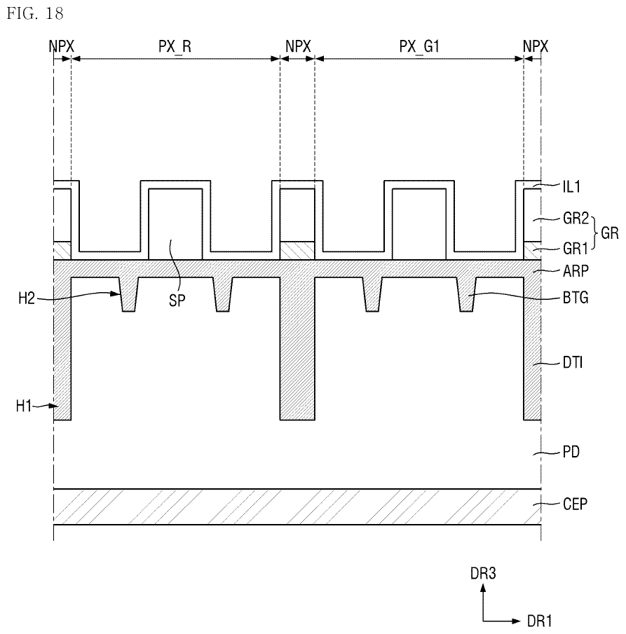

As illustrated in FIGS. 4 and 18, in the region in which the carbon layer CL′ is formed in FIG. 17, the scattering portion SP and the second grid portion GR2 are formed. The scattering portion SP is formed in the pixel regions PX_R and PX_G1, and the second grid portion GR2 is formed in the non-pixel region NPX.

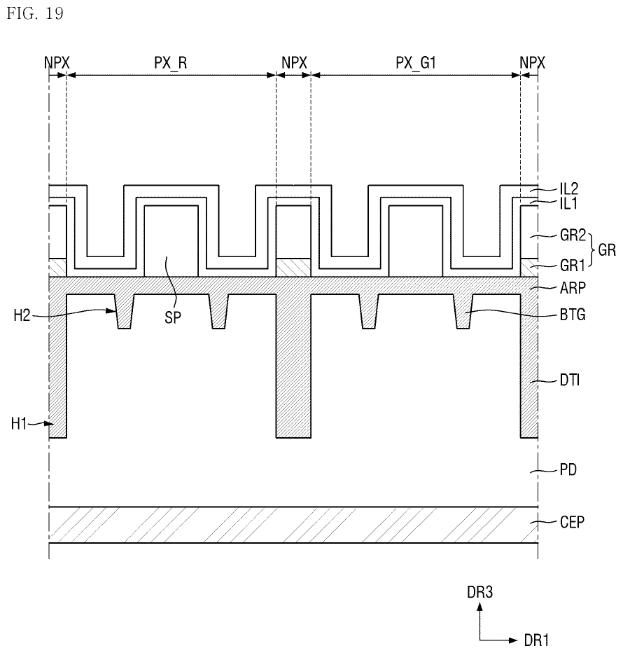

As illustrated in FIGS. 4 and 19, the second insulation layer IL2 is formed on the first insulation layer IL1. The second insulation layer IL2 may include an insulation material. For example, the second insulation layer IL2 may include silicon oxide (SiO2), but is not limited thereto.

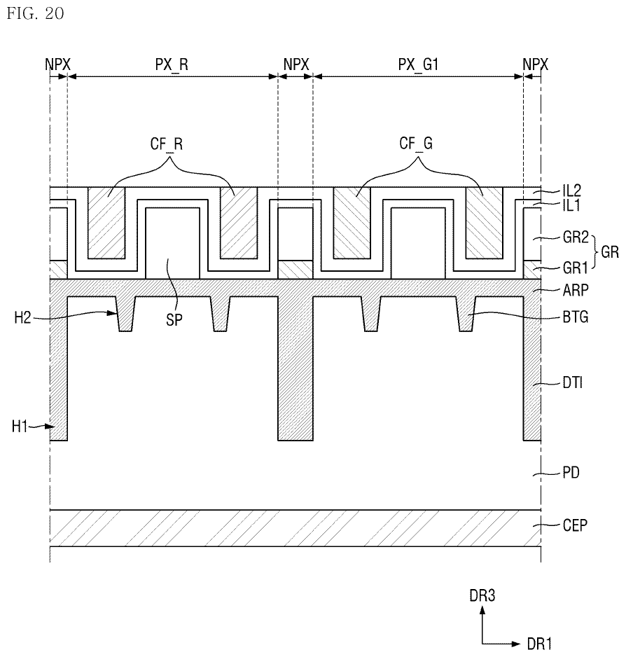

As illustrated in FIGS. 4 and 20, the color filters CF_R and CF_G are disposed on the second insulation layer IL2 in the pixel regions PX_R and PX_G1. The first color filter CF_R may receive the light in the red wavelength range and the ultraviolet wavelength range, block light in the remaining wavelength ranges, and the second color filter CF_G may receive light in the green wavelength range and the ultraviolet wavelength range, and block light in the remaining wavelength ranges. Surfaces of the color filters CF_R and CF_G may be positioned to be collinear with a surface of the second insulating layer IL2, but are not limited thereto.

Hereinafter, a pixel array of an image sensing device based on some embodiments will be described. Redundant description of the reference numerals or components which have been described with reference to FIGS. 1 to 20 will be omitted, or the detailed description thereof will be omitted.

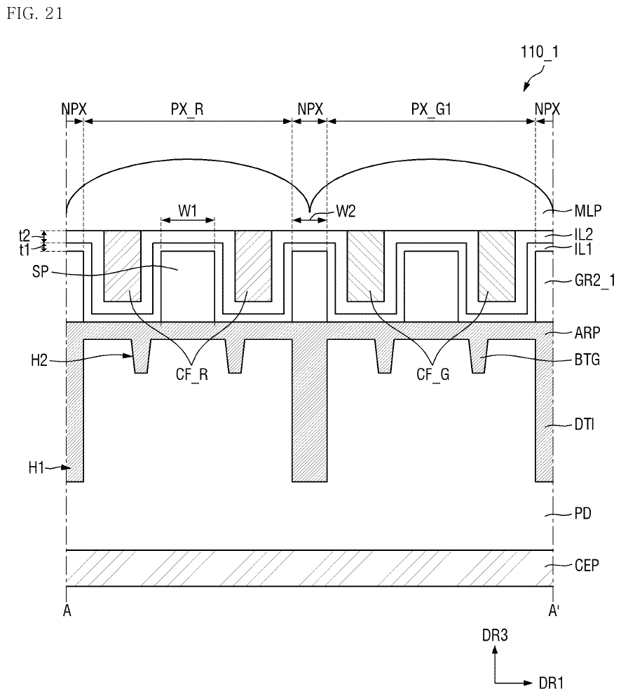

FIG. 21 is a cross-sectional view of a pixel array of an image sensing device based on another embodiment of the disclosed technology.

Referring to FIG. 21, a pixel array 110_1 is different from the pixel array 110 illustrated in FIG. 4 in that a grid portion GR_1 of the pixel array 110_1 does not include the first grid portion GR1 in FIG. 4.

To describe it in more detail, the grid portion GR_1 may be formed by including the second grid portion GR2 according to FIG. 4 only. The grid portion GR_1 may include the air structure. The grid portion GR_1 may serve to totally reflect the light incident on the grid portion GR_1. The grid portion GR_1 may prevent color mixing between the neighboring pixel regions PX_R and PX_G1. In addition, the grid portion GR_1 according to FIG. 21 has an effect of improving the optical loss because the grid portion GR_1 according to FIG. 21 does not include the first grid portion GR1 according to FIG. 4 which absorbs light.

In an embodiment, the scattering portion SP is disposed in the pixel regions PX_R and PX_G1, and the scattering portion SP may include a material having a lower refractive index than the refractive index of the light concentrating pattern MLP on the upper surface and the color filters CF_R and CF_G. The light incident on the scattering portion SP may be scattered and increase the path of the light incident through the light concentrating pattern MLP. Because of this, the quantum efficiency (QE) of the photodiode PD may be improved.

In addition, the scattering portion SP may be positioned inside the color filters CF_R and CF_G in a planar view. The light incident through the light concentrating pattern MLP is scattered by the scattering portion SP, therefore, it is possible to prevent the incident light from being focused in the color filters CF_R and CF_G. Because of this, it is possible to improve a property change of the color filters CF_R and CF_G.

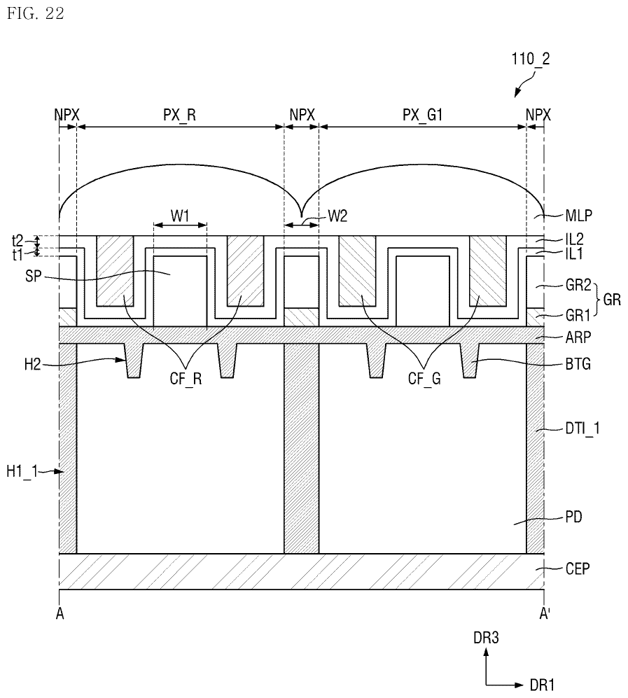

FIG. 22 is a cross-sectional view of a pixel array of an image sensing device based on another embodiment of the disclosed technology.

Referring to FIG. 22, a first groove H1_1 of the pixel array 110_2 is different from the first groove H1 illustrated in FIG. 4 in that the first groove H1_1 of the pixel array 110_2 completely passes through the photodiode PD. In the first groove H1_1, a first trench portion DTI_1 is disposed, and a bottom surface of the first trench portion DTI_1 contacts the circuitry CEP, and an upper surface thereof may contact the anti-reflection layer ARP. The first trench portion DTI_1 may include a material different from a material of the second trench portion BTG. For example, the first trench portion DTI_1 may include poly silicon, but is not limited thereto. The first trench portion DTI_1 may include the same material as the material of the second trench portion BTG.

In an embodiment, the scattering portion SP is disposed in the pixel regions PX_R and PX_G1, and the scattering portion SP may include a material having a lower refractive index than the refractive index of the light concentrating pattern MLP on the upper surface and the color filters CF_R and CF_G. The light incident on the scattering portion SP may be scattered and may increase the path of the light incident through the light concentrating pattern MLP. Because of this, the quantum efficiency (QE) of the light may be improved.

In addition, the scattering portion SP may be positioned inside the color filters CF_R and CF_G in a planar view. The light incident through the light concentrating pattern MLP is scattered by the scattering portion SP, therefore, it is possible to prevent the incident light from being focused in the color filters CF_R and CF_G. Because of this, it is possible to improve a property change of the color filters CF_R and CF_G.

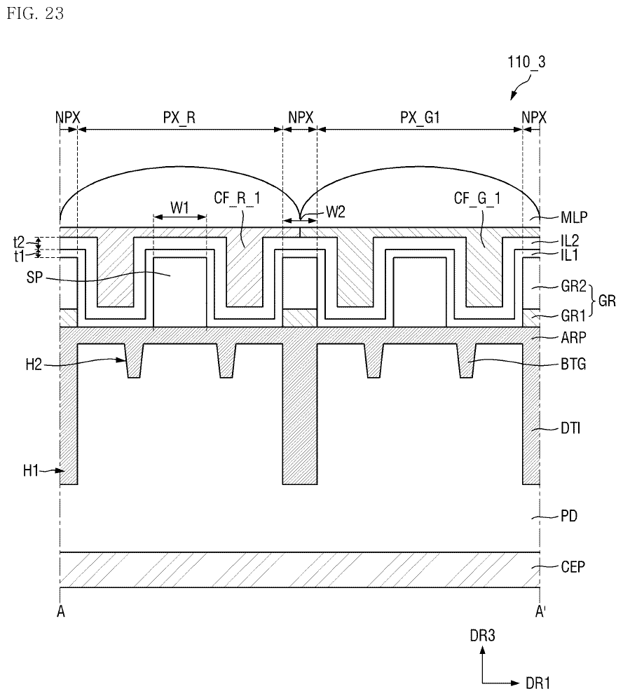

FIG. 23 is a cross-sectional view of a pixel array of an image sensing device based on another embodiment of the disclosed technology.

Referring to FIG. 23, a pixel array 110_3 is different from the pixel array 110 illustrated in FIG. 4 in that each of the color filters CF_R_1 and CF_G_1 of the pixel array 110_3 overlap the scattering portion SP.

In some implementations, surfaces of the color filters CF_R_1 and CF_G_1 may be higher than a surface of the second insulation layer IL2. The color filters CF_R_1 and CF_G_1 may overlap the scattering portion SP and the grid portion GR.

In an embodiment, the scattering portion SP may be disposed in the pixel regions PX_R and PX_G1, and the scattering portion SP may include a material having a lower refractive index than the refractive index of the materials of the light concentrating pattern MLP on the upper surface and the color filters CF_R and CF_G. The light incident on the scattering portion SP is scattered and may increase the path of the light incident through the light concentrating pattern MLP. Because of this, it is possible to improve the quantum efficiency (QE) of the light.

In addition, the scattering portion SP may be positioned inside the color filters CF_R and CF_G in a planar view. The light incident through the light concentrating pattern MLP is scattered by the scattering portion SP, therefore, it is possible to prevent the incident light from being focused in the color filters CF_R and CF_G. Because of this, it is possible to improve a property change of the color filters CF_R and CF_G.

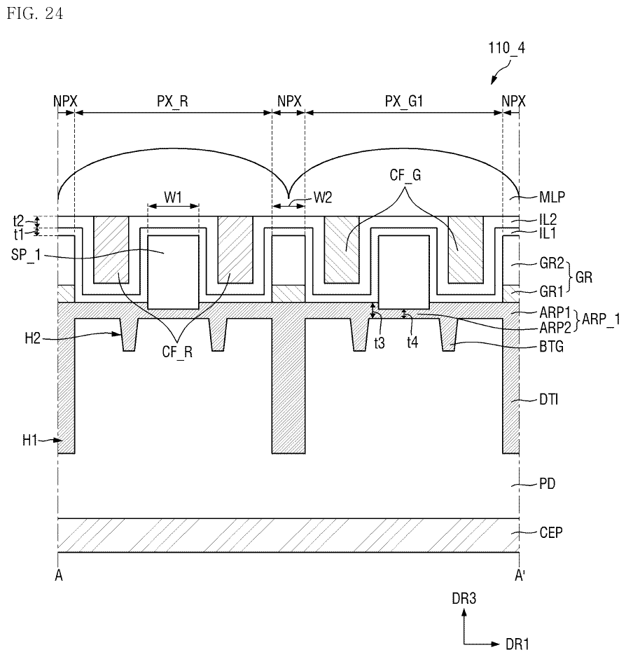

FIG. 24 is a cross-sectional view of a pixel array of an image sensing device based on another embodiment of the disclosed technology.

Referring to FIG. 24, a pixel array 110_4 is different from the pixel array 110 illustrated in FIG. 4 in that an anti-reflection layer ARP_1 of the pixel array 110_4 may include a first anti-reflection layer ARP1 and a second anti-reflection layer ARP2.

In some implementations, a thickness t4 of the second anti-reflection layer ARP2 may be smaller than a thickness t3 of the first anti-reflection layer ARP1. The scattering portion SP may extend partially through the second anti-reflection layer ARP2.

In an embodiment, a scattering portion SP_1 may extend partially through the anti-reflection layer ARP1 and be further expanded compared to the scattering portion SP in FIG. 4. Because of this, the scattering effect by the scattering portion SP_1 and the anti-focusing effect in the color filters CF_R and CF_G may be further improved.

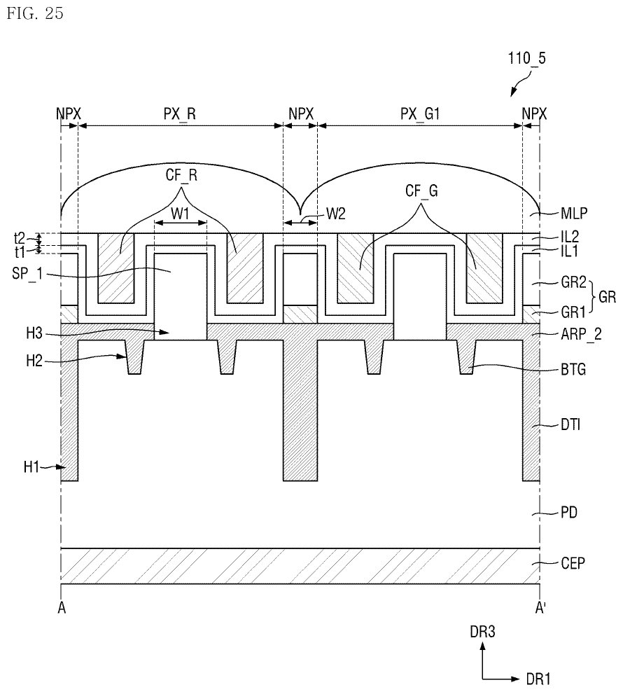

FIG. 25 is a cross-sectional view of a pixel array of an image sensing device based on another embodiment of the disclosed technology.

Referring to FIG. 25, a pixel array 110_5 is different from the pixel array 110 illustrated in FIG. 4 in that a scattering portion SP_2 of the pixel array 110_5 completely passes through an anti-reflection layer ARP_2.

In an embodiment, the scattering portion SP_2 may completely pass through the anti-reflection layer ARP_2 and be further expanded compared to the scattering portion SP_1 in FIG. 24. Because of this, the scattering effect by the scattering portion SP_2 and the anti-focusing effect in the color filters CF_R and CF_G may be further improved.

The scattering portion SP_2 may directly contact the photodiode PD.

Other components illustrated in FIG. 25 are similar to the components discussed above with reference to FIGS. 4 and 24, and thus further descriptions thereof will be omitted here.

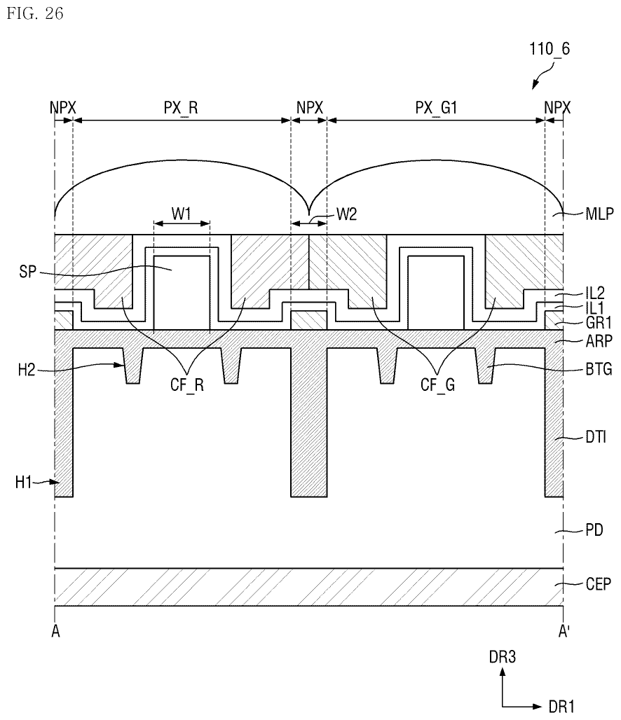

FIG. 26 is a cross-sectional view of a pixel array of an image sensing device based on another embodiment of the disclosed technology.

Referring to FIG. 26, a pixel array 110_6 is different from the pixel array 110 illustrated in FIG. 4 in that the grid portion of the pixel array 110_6 includes the first grid portion GR1 only.

In an embodiment, the first insulation layer IL1 may directly contact an upper surface of the first grid portion GR1. The color filters CF_R and CF_G may be disposed in the non-pixel region NPX as well.

In an embodiment, the scattering portion SP may be disposed in the pixel regions PX_R and PX_G1, and the scattering portion SP may include a material having a lower refractive index than the refractive index of the materials of the light concentrating pattern MLP on the upper surface and the color filters CF_R and CF_G. The light incident on the scattering portion SP is scattered and may increase the path of the light incident through the light concentrating pattern MLP. Because of this, it is possible to improve the quantum efficiency (QE) of the light.

In addition, the scattering portion SP may be positioned inside the color filters CF_R and CF_G in a planar view. The light incident through the light concentrating pattern MLP is scattered by the scattering portion SP, therefore, it is possible to prevent the incident light from being focused in the color filters CF_R and CF_G. Because of this, it is possible to improve a property change of the color filters CF_R and CF_G.

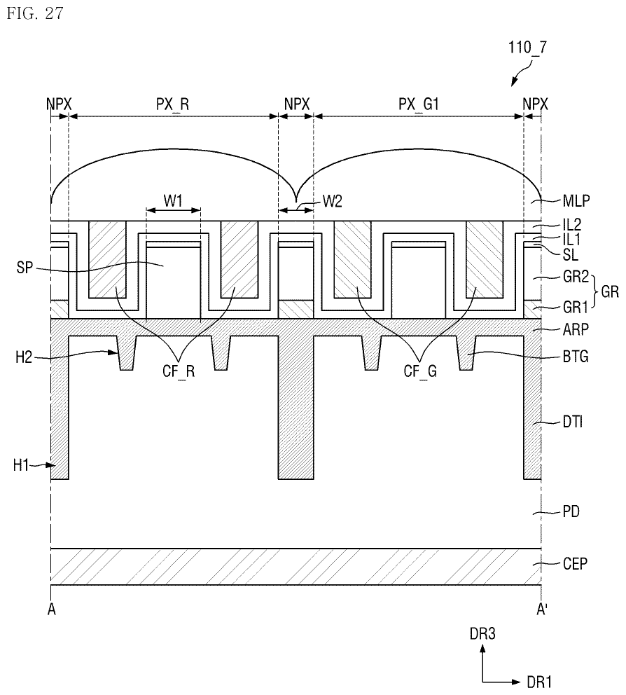

FIG. 27 is a cross-sectional view of a pixel array of an image sensing device based on another embodiment of the disclosed technology.

Referring to FIG. 27, a pixel array 110_7 is different from the pixel array 110 illustrated in FIG. 4 in that the pixel array 110_7 further includes the stopper layer SL in the non-pixel region NPX between the second grid portion GR2 and the first insulation layer IL1. The stopper layer SL may include silicon nitride (SiNx).

In an embodiment, in the course of removing the second photoresist PR2 and the stopper layer SL″ as show in FIG. 15, remaining the stopper layer SL″ as the stopper layer SL without completely removing the stopper layer SL″ is taken as an example. A thickness of the stopper layer SL may be smaller than a thickness of the stopper layer SL″ as show in FIG. 14.

In an embodiment, the scattering portion SP may be disposed in the pixel regions PX_R and PX_G1, and the scattering portion SP may include a material having a lower refractive index than the refractive index of the materials of the light concentrating pattern MLP on the upper surface and the color filters CF_R and CF_G. The light incident on the scattering portion SP is scattered and may increase the path of the light incident through the light concentrating pattern MLP. Because of this, it is possible to improve the quantum efficiency (QE) of the light.

In addition, the scattering portion SP may be positioned inside the color filters CF_R and CF_G in a planar view. The light incident through the light concentrating pattern MLP is scattered by the scattering portion SP, therefore, it is possible to prevent the incident light from being focused in the color filters CF_R and CF_G. Because of this, it is possible to improve a property change of the color filters CF_R and CF_G.

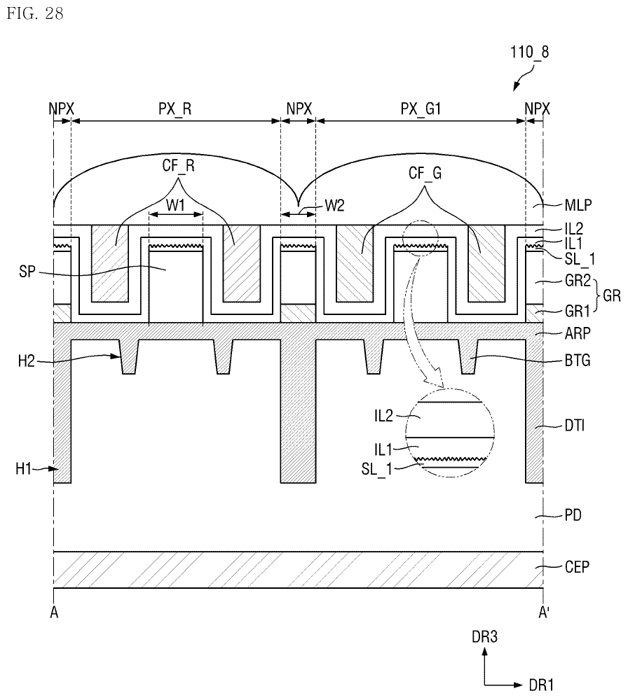

FIG. 28 is a cross-sectional view of a pixel array of an image sensing device based on another embodiment of the disclosed technology.

Referring to FIG. 28, different from the pixel array 110_7 illustrated in FIG. 27, a pixel array 110_8 based on some embodiments includes a stopper layer SL_1 that includes an uneven surface. For example, the stopper layer SL_1 of the pixel array 110_8 includes a surface that includes concave shapes and/or convex shapes. Other components illustrated in FIG. 28 are similar to the components discussed above with reference to FIG. 27, and thus further descriptions thereof will be omitted here.

In an embodiment, the scattering portion SP may be disposed in the pixel regions PX_R and PX_G1, and the scattering portion SP may include a material having a lower refractive index than the refractive index of the materials of the light concentrating pattern MLP on the upper surface and the color filters CF_R and CF_G. The light incident on the scattering portion SP is scattered and may increase the path of the light incident through the light concentrating pattern MLP. Because of this, it is possible to improve the quantum efficiency (QE) of the light.

In addition, the scattering portion SP may be positioned inside the color filters CF_R and CF_G in a planar view. The light incident through the light concentrating pattern MLP is scattered by the scattering portion SP, therefore, it is possible to prevent the incident light from being focused in the color filters CF_R and CF_G. Because of this, it is possible to improve a property change of the color filters CF_R and CF_G.

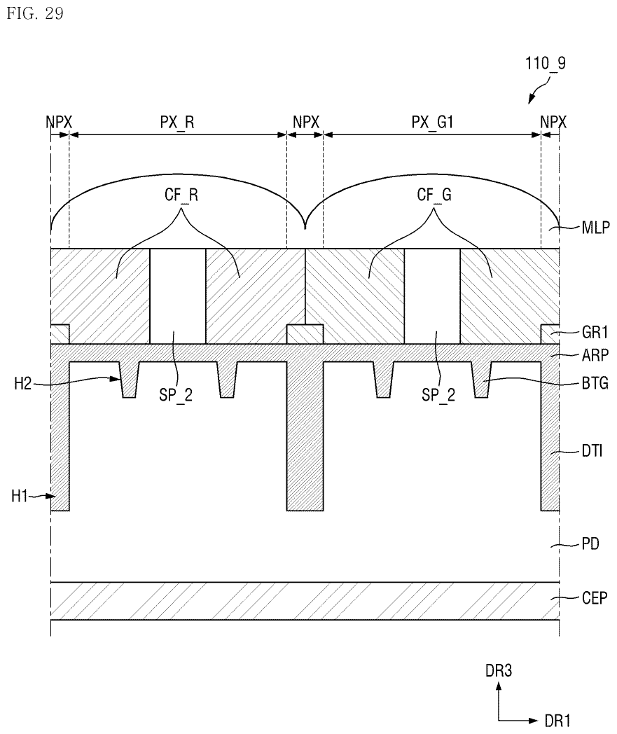

FIG. 29 is a cross-sectional view of a pixel array of an image sensing device based on another embodiment of the disclosed technology.

Referring to FIG. 29, a pixel array 110_9 is different from the pixel array 110 illustrated in FIG. 4 in that the pixel array 110_9 includes a second scattering portion SP_2.

In some implementations, the second scattering portion SP_2 may be formed by completely passing through the color filters CF_R and CF_G1. A bottom surface of the second scattering portion SP_2 may contact the anti-reflection layer ARP, and an upper surface thereof may contact the light concentrating pattern MLP. The second scattering portion SP_2 may include a low refractive insulation material. For example, the second scattering portion SP_2 may have a refractive index between a refractive index of the light concentrating pattern MLP and a refractive index of the color filters CF_R and CF_G.

In an embodiment, the scattering portion SP_2 may be disposed in the pixel regions PX_R and PX_G1, and the scattering portion SP_2 may include a material having a lower refractive index than the refractive index of the materials of the light concentrating pattern MLP on the upper surface and the color filters CF_R and CF_G. The light incident on the scattering portion SP_2 is scattered and may increase the path of the light incident through the light concentrating pattern MLP. Because of this, it is possible to improve the quantum efficiency (QE) of the light.

In addition, the scattering portion SP_2 may be positioned inside the color filters CF_R and CF_G in a planar view. The light incident through the light concentrating pattern MLP is scattered by the scattering portion SP_2, therefore, it is possible to prevent the incident light from being focused in the color filters CF_R and CF_G. Because of this, it is possible to improve a property change of the color filters CF_R and CF_G.

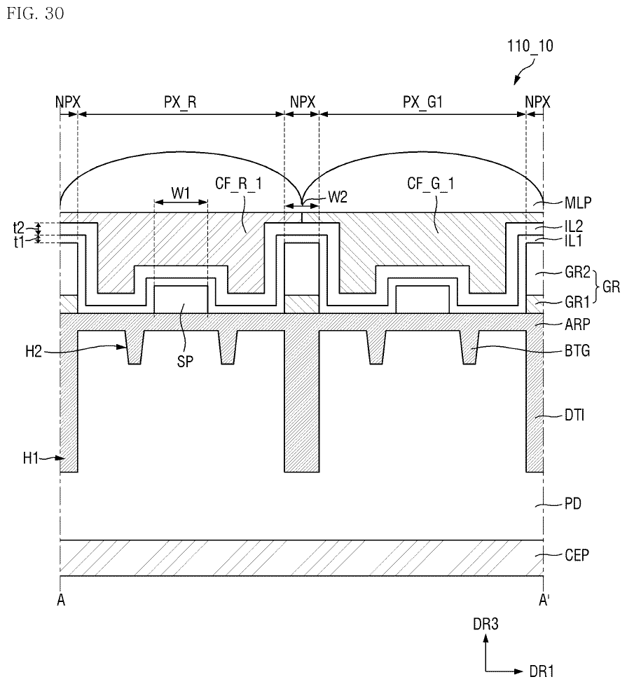

FIG. 30 is a cross-sectional view of a pixel array of an image sensing device based on another embodiment of the disclosed technology.

Referring to FIG. 30, a pixel array 110_10 is different from the pixel array 110_3 illustrated in FIG. 23 in that a surface height of the scattering portion SP of the pixel array 110_10 is lower than a surface height of the second grid portion GR2.

The surface height of the scattering portion SP may be lower than a surface height of the scattering portion SP in FIG. 23. In some embodiments, the surface height of the scattering portion SP is lowered, an area of the color filters CF_R and CF_G may be secured, and therefore, deterioration of functions of the color filters CF_R and CF_G due to a volume of the scattering portion SP may be improved. In FIG. 30, it is illustrated that the color filters CF_R and CF_G are disposed in the non-pixel region NPX as well, however, the disclosed technology is not limited thereto, and the color filters CF_R and CF_G may not be disposed in the non-pixel region NPX. That is, because a thickness of the second grid portion GR2 is increased, there is an effect that color mixing problem between the neighboring pixel regions PX_R and PX_G1 may be improved.

The image sensing device based on some embodiments may include the following features.

In an embodiment, an image sensing device may include a circuitry region in which a pixel region and a non-pixel region around the pixel region are defined; a photodiode on the circuitry region; a trench portion disposed inside the photodiode in the pixel region; a scattering portion disposed on the photodiode in the pixel region; a color filter disposed on the photodiode and the trench portion; and a light concentrating pattern disposed on the color filter, and a refractive index of the scattering portion may be lower than a refractive index of the color filter and a refractive index of the light concentrating pattern.

The image sensing device based on some embodiments of the disclosed technology may further include: an anti-reflection layer between the scattering portion and the photodiode, and a refractive index of the anti-reflection layer may have a value between a refractive index of the scattering portion and a refractive index of the photodiode.

In some embodiments of the disclosed technology, the scattering portion may include an air structure.

In some embodiments of the disclosed technology, the image sensing device may further include: a first insulation layer configured to cap the scattering portion between the scattering portion and the color filter.

In some embodiments of the disclosed technology, the image sensing device may further include: a second insulation layer disposed between the first insulation layer and the color filter, and a thickness of the second insulation layer may be greater than a thickness of the first insulation layer.

In some embodiments of the disclosed technology, a free volume of the first insulation layer may be greater than a free volume of the second insulation layer.

In some embodiments of the disclosed technology, the color filter may be disposed between the second insulation layer and the light concentrating pattern.

In some embodiments of the disclosed technology, The image sensing device may further include: a stopper layer disposed between the scattering portion and the first insulation layer, and a surface of the stopper layer may include a concave-convex shape.

In some embodiments of the disclosed technology, the scattering portion may extend partially or completely pass through the anti-reflection layer in a thickness direction.

In some embodiments of the disclosed technology, a first groove may be formed in a thickness direction on the photodiode in the non-pixel region, a second groove may be formed in the thickness direction on the photodiode in the pixel region, a depth of the first groove may be greater than a depth of the second groove, and the trench portion may include a first trench portion disposed in the first groove and a second trench portion disposed in the second groove.

In some embodiments of the disclosed technology, each of the anti-reflection layer, the first trench portion, and the second trench portion may have a same material.

In some embodiments of the disclosed technology, the first trench portion may have a different material from a material of the anti-reflection layer and a material of the second trench portion, and a refractive index of the first trench portion may be lower than the refractive index of the photodiode.

In some embodiments of the disclosed technology, the first groove may completely pass through the photodiode in the thickness direction.

In some embodiments of the disclosed technology, the image sensing device may further include: a grid portion disposed on the photodiode in the non-pixel region.

In some embodiments of the disclosed technology, the grid portion may include: a first grid portion; and a second grid portion disposed on the first grid portion, and the first grid portion may include a metal, and the second grid portion may include the air structure.

In some embodiments of the disclosed technology, the grid portion may include the air structure.

In some embodiments of the disclosed technology, a width of the scattering portion may be greater than a width of the grid portion.

Another embodiment is an image sensing device, including: a circuitry region in which a pixel region and a non-pixel region around the pixel region are defined; a photodiode on the circuitry region; a color filter disposed on the photodiode; a scattering portion disposed inside the color filter in the pixel region; and a light concentrating pattern disposed on the color filter and the scattering portion, and a refractive index of the scattering portion may be lower than a refractive index of the color filter and a refractive index of the light concentrating pattern.

In some embodiments of the disclosed technology, the scattering portion may include a low refractive insulation material.

In another embodiment, a method for manufacturing an image sensing device may include: forming a photodiode layer on a circuitry region in which a pixel region and a non-pixel region around the pixel region are defined; forming a first trench portion in the non-pixel region and a second trench portion in the pixel region inside the photodiode into which the photodiode layer is etched; forming an anti-reflection layer on the photodiode; forming a first grid portion on the anti-reflection layer in the non-pixel region; forming a carbon layer and a stopper layer on the first grid portion and the anti-reflection layer; etching the carbon layer and the stopper layer; forming a first insulation layer on the etched carbon layer and the etched stopper layer; and oxidizing the carbon layer and forming a scattering portion in the pixel region and a second grid portion in the non-pixel region.

In some embodiments of the disclosed technology, the forming a first trench portion in the non-pixel region and a second trench portion in the pixel region inside the photodiode into which the photodiode layer is etched and the forming an anti-reflection layer on the photodiode may be performed simultaneously.

In some embodiments of the disclosed technology, the method may further include: forming a second insulation layer on the first insulation layer, and a thickness of the second insulation layer may be greater than a thickness of the first insulation layer, and a free volume of the first insulation layer may be greater than a free volume of the second insulation layer.

In some embodiments of the disclosed technology, the method may further include: forming a color filter on the second insulation layer and forming a light concentrating pattern on the color filter.

In some embodiments of the disclosed technology, a refractive index of the scattering portion may be lower than a refractive index of the color filter and a refractive index of the light concentrating pattern.

Only a few implementations and examples are described and other implementations, enhancements and variations can be made based on what is described and illustrated in this patent document.

What is claimed is:

1. An image sensing device, comprising:
a circuitry region including a pixel region and a non-pixel region disposed around the pixel region;
a photodiode disposed in the circuitry region;
a trench portion extending from a top of the photodiode toward a bottom of the photodiode;
a scattering portion disposed on the photodiode in the pixel region and structured to scatter light entering the pixel region;
a color filter disposed over the photodiode and the trench portion; and
a light concentrating pattern disposed on the color filter and structured to direct the light toward the pixel region,
wherein a refractive index of the scattering portion is lower than a refractive index of the color filter and a refractive index of the light concentrating pattern.

2. The image sensing device of claim 1, further comprising:
an anti-reflection layer disposed between the scattering portion and the photodiode to reduce reflection of light,
wherein a refractive index of the anti-reflection layer has a value between a refractive index of the scattering portion and a refractive index of the photodiode.

3. The image sensing device of claim 2, wherein the scattering portion includes air.

4. The image sensing device of claim 3, further comprising:
a first insulation layer configured to cover the scattering portion between the scattering portion and the color filter.

5. The image sensing device of claim 4, further comprising:
a second insulation layer disposed between the first insulation layer and the color filter,
wherein a thickness of the second insulation layer is greater than a thickness of the first insulation layer.

6. The image sensing device of claim 5, wherein a free volume of the first insulation layer is greater than a free volume of the second insulation layer.

7. The image sensing device of claim 5, wherein the color filter is disposed between the second insulation layer and the light concentrating pattern.

8. The image sensing device of claim 4, further comprising:
a stopper layer disposed between the scattering portion and the first insulation layer,
wherein the stopper layer includes an uneven surface.

9. The image sensing device of claim 2, wherein the scattering portion is structured to extend partially through or completely pass through the anti-reflection layer in a thickness direction.

10. The image sensing device of claim 2,
wherein the trench portion comprises a first trench portion disposed in a first groove and a second trench portion disposed in a second groove, wherein the first groove is formed in a thickness direction on the photodiode in the non-pixel region, and the second groove is formed in the thickness direction on the photodiode in the pixel region, wherein a depth of the first groove is greater than a depth of the second groove.

11. The image sensing device of claim 10, wherein each of the anti-reflection layer, the first trench portion, and the second trench portion includes a same material.

12. The image sensing device of claim 10, wherein the first trench portion includes a different material from a material of the anti-reflection layer and a material of the second trench portion, and
wherein a refractive index of the first trench portion is lower than the refractive index of the photodiode.

13. The image sensing device of claim 10, wherein the first groove completely passes through the photodiode in the thickness direction.

14. The image sensing device of claim 3, further comprising:
a grid portion disposed on the photodiode in the non-pixel region.

15. The image sensing device of claim 14, wherein the grid portion comprises:
a first grid portion; and
a second grid portion disposed on the first grid portion,
wherein the first grid portion includes a metal, and
wherein the second grid portion includes air.

16. The image sensing device of claim 14, wherein the grid portion includes air.

17. The image sensing device of claim 14, wherein a width of the scattering portion is greater than a width of the grid portion.

18. An image sensing device, comprising:
a circuitry region including a pixel region and a non-pixel region disposed around the pixel region;
a photodiode disposed in the circuitry region;
a color filter disposed on the photodiode;
a scattering portion disposed inside the color filter in the pixel region and structured to scatter light entering the pixel region; and
a light concentrating pattern disposed on the color filter and the scattering portion and structured to direct the light toward the pixel region,
wherein a refractive index of the scattering portion is lower than a refractive index of the color filter and a refractive index of the light concentrating pattern.

19. The image sensing device of claim 18, wherein the scattering portion comprises an insulation material with a refractive index lower than a refractive index of an adjacent material layer.

20. A method for manufacturing an image sensing device, comprising:
forming a photodiode layer that includes a photodiode on a circuitry region that includes a pixel region and a non-pixel region disposed around the pixel region;
forming a first trench portion in the non-pixel region and a second trench portion in the pixel region inside the photodiode layer by etching part of the photodiode layer;
forming an anti-reflection layer on the photodiode layer;
forming a first grid portion on the anti-reflection layer in the non-pixel region;
forming a carbon layer and a stopper layer on the first grid portion and the anti-reflection layer;
etching the carbon layer and the stopper layer to form an etched carbon layer and an etched stopper layer;
forming a first insulation layer on the etched carbon layer and the etched stopper layer; and
oxidizing the carbon layer and forming a scattering portion in the pixel region and a second grid portion in the non-pixel region.

21. The method of claim 20, wherein the forming the first trench portion in the non-pixel region and the second trench portion in the pixel region inside the photodiode layer and the forming the anti-reflection layer on the photodiode layer are performed simultaneously.

22. The method of claim 20, further comprising:
forming a second insulation layer on the first insulation layer,
wherein a thickness of the second insulation layer is greater than a thickness of the first insulation layer, and
wherein a free volume of the first insulation layer is greater than a free volume of the second insulation layer.

23. The method of claim 22, further comprising:
forming a color filter on the second insulation layer; and
forming a light concentrating pattern on the color filter.

24. The method of claim 23, wherein a refractive index of the scattering portion is lower than a refractive index of the color filter and a refractive index of the light concentrating pattern.
